(19) United States
(12) Patent Application Publication
(10) Pub. No.: US 2024/0339423 A1
(43) Pub. Date: Oct. 10, 2024

(54) SEMICONDUCTOR PACKAGING STRUCTURE AND METHOD FOR FORMING THE SAME

(71) Applicant: CXMT CORPORATION, Hefei (CN)

(72) Inventor: LING-YI CHUANG, Hefei (CN)

(21) Appl. No.: 18/747,462

(22) Filed: Jun. 19, 2024

Related U.S. Application Data
(63) Continuation of application No. PCT/CN2022/125367, filed on Oct. 14, 2022.

(30) Foreign Application Priority Data
Jan. 20, 2022 (CN) 202210068308.4

(51) Int. Cl. H01L 23/00; H01L 25/18

(52) U.S. Cl. CPC H01L 24/08; H01L 24/03; H01L 24/06; H01L 24/80; H01L 25/18; H01L 2224/03831; H01L 2224/0603; H01L 2224/08145; H01L 2224/80895; H01L 2224/80896; H01L 2225/06544; H01L 2924/1815

(57) ABSTRACT

A semiconductor packaging structure and a method for forming the same are provided. A first semiconductor chip with first contact pads formed on a surface of the first semiconductor chip. A dielectric layer disposed on the first semiconductor chip with second contact pads formed in the dielectric layer. A second semiconductor chip stack structure disposed on the dielectric layer with third contact pads formed on the surface of the second semiconductor chip stack structure. The first semiconductor chip and the second semiconductor chip stacking structure are bonded to each other one-to-one by the first contact pads, the second contact pads and the third contact pads. a width of each of the second-contact-pads is not consistent with a width of each of corresponding first-contact-pads or a width of each of corresponding third-contact-pads.

### CROSS-REFERENCE TO RELATED APPLICATIONS

The present application is a continuation of PCT/CN2022/125367, filed on Oct. 14, 2022, which claims priority to the Chinese Patent Application No. 202210068308.4 filed on Jan. 20, 2022, the disclosure of which is hereby incorporated by reference in its entirety.

### TECHNICAL FIELD

The present disclosure relates to, but is not limited to, a semiconductor packaging structure and a method for forming the same.

### BACKGROUND

As requirements for electronic products are developing towards miniaturization and multifunction, packaging is also developing towards high density and high integration, and integrated circuit products are also developing from two-dimensional to three-dimensional. However, in the process of chip bonding, misalignment between contact-pads may occur, which affects the performance of devices.

### SUMMARY

In view of this, embodiments of the disclosure provide a semiconductor packaging structure and a method for forming the same.

According to a first aspect of the embodiments of the disclosure, a semiconductor packaging structure is provided, including:
A first semiconductor chip; wherein first contact pads are formed on a surface of the first semiconductor chip;
A dielectric layer located on the first semiconductor chip; wherein second-contact-pads are formed within the dielectric layer; and
A second semiconductor chip stacking structure located on the dielectric layer; wherein the second semiconductor chip stacking structure includes a plurality of layers of second semiconductor chips stacked in sequence; and third-contact-pads are formed on a surface of a first layer of the plurality of layers of the second semiconductor chips;
Wherein the first semiconductor chip and the first layer of the plurality of layers of the second semiconductor chips are bonded to each other in an one-to-one correspondence manner through the first-contact-pads, the second-contact-pads and the third-contact-pads; wherein,
A width of each of the second-contact-pads is inconsistent with a width of each of corresponding first-contact-pads or a width of each of corresponding third-contact-pads.

### BRIEF DESCRIPTION OF THE DRAWINGS

In order to explain the technical solutions in the embodiments of the present disclosure, the drawings needed to be used in the description of the embodiments will be briefly introduced below. It is apparent that the drawings described below are only some embodiments of the present disclosure, and other drawings may be obtained from them without creative effort for those of skilled in the art.

FIG. 1A is a schematic structural diagram of a semiconductor packaging structure provided in an embodiment of the present disclosure;

FIG. 1B is a schematic structural diagram of a semiconductor packaging structure provided in another embodiment of the present disclosure;

FIG. 2 is a flow diagram of a method for forming a semiconductor packaging structure provided in an embodiment of the present disclosure;

FIGS. 3A to 3I are schematic structural diagrams of a semiconductor packaging structure during the forming process provided in an embodiment of the present disclosure.

### DETAILED DESCRIPTION

Exemplary embodiments of the present disclosure will be described in more detail below with reference to the accompanying drawings. While exemplary embodiments of the present disclosure are shown in the accompanying drawings, it should be understood that the present disclosure may be implemented in various forms and should not be limited by the specific embodiments set forth herein. Instead, these embodiments are provided so that the disclosure may be understood more thoroughly, and the scope of the disclosure may be fully conveyed to those skilled in the art.

In the following description, numerous specific details are given to provide a more thorough understanding of the disclosure. However, it may be apparent to those skilled in the art that the present disclosure may be implemented without one or more of these details. In other examples, some technical features that are well known in the art have not been described in order to avoid confusion with the present disclosure; that is, not all the features of an actual embodiment are described herein, and the well-known functions and structures are not described in detail.

In the accompanying drawings, sizes of layers, regions and elements, and relative sizes thereof may be exaggerated for clarity. The same reference number always refers to the same element.

It should be understood that when an element or layer is referred to as being “located on”, “adjacent to”, “connected to” or “coupled to” another element or layer, it may be directly located on another element or layer, adjacent to another element or layer, connected to or coupled to another element or layer, or an intervening element or layer may be present. In contrast, when an element is referred to as being “directly located on”, “directly adjacent to”, “directly connected to” or “directly coupled to” another element or layer, there is no intervening element or layer. It should be understood that although terms first, second, third, or the like may be used to describe various elements, components, regions, layers and/or portions, these elements, components, regions, layers and/or portions should not be limited by these terms. These terms are only used to distinguish one element, component, region, layer or portion from another element, component, region, layer or portion. Therefore, a first element, component, region, layer or portion discussed below may be represented as a second element, component, region, layer or portion, without departing from teaching of the disclosure. While discussion of a second element, component, region, layer or portion does not imply that a first element, component, region, layer or portion is necessarily present in the disclosure.

Spatial relationship terms such as “underneath”, “under”, “below”, “beneath”, “over”, “above”, etc. may be used herein for convenience of description to describe the relationship between one element or feature and other elements or features shown in the drawings. It should be understood that, in addition to the orientations shown in the drawings, the spatial relationship term are also intended to encompass different orientations of devices in use and operation. For example, if the device in the drawings is turned upside down, then the element or feature described as “under” or “below” or “beneath” the other element or feature will be oriented “over” the other element or feature. Thus, the exemplary terms “below” and “under” may include both upper and lower orientations. The device may be additionally oriented (e.g. rotating 90 degrees or other orientations) and the spatial descriptors used herein are interpreted accordingly.

The terms used herein are for the purpose of describing specific embodiments only and are not to be used as a limitation of the present disclosure. As used herein, singular forms of “a”, “an” and “said/the” may also include plural forms, unless the context clearly indicates other forms. It should also be understood that when used in the description, terms “compose” and/or “include” determine presence of said features, integers, steps, operations, elements and/or components, but do not exclude presence or addition of one or more of other features, integers, steps, operations, elements, components and/or groups. As used herein, a term “and/or” includes any and all combinations of related listed items.

In order to thoroughly understand the present disclosure, detailed steps and detailed structure will be set forth in the following description in order to illustrate the technical solution of the present disclosure. Preferred embodiments of the present disclosure are described in detail below, however, the present disclosure may have other embodiments in addition to these detailed descriptions.

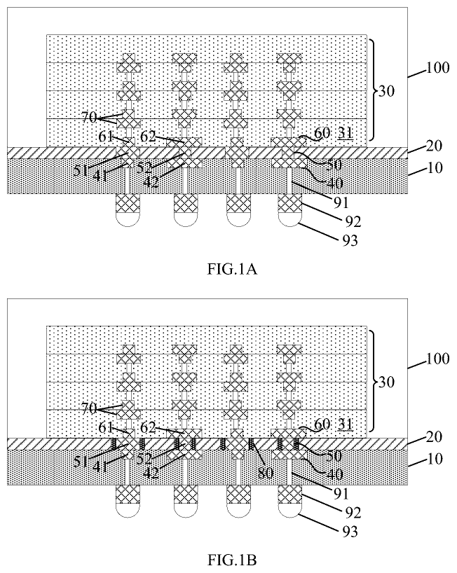

Based on this, embodiments of the present disclosure provide a semiconductor packaging structure, and FIG. 1A is a schematic structural diagram of a semiconductor packaging structure provided in an embodiment of the present disclosure.

With Reference to FIG. 1A, the semiconductor packaging structure includes: a first semiconductor chip 10; a plurality of first-contact-pads 40 are formed on a surface of the first semiconductor chip; a dielectric layer 20 located on the first semiconductor chip 10; and a plurality of second-contact-pads 50 are formed within the dielectric layer 20; a second semiconductor chip stacking structure 30 located on the dielectric layer 20; the second semiconductor chip stacking structure 30 includes a plurality of layers of second semiconductor chips stacked in sequence; a plurality of third-contact-pads 60 are formed on a surface of a first layer 31 of the plurality of layers of the second semiconductor chips; the first semiconductor chip 10 and the first layer 31 of the plurality of layers of the second semiconductor chips are bonded to each other in an one-to-one correspondence manner by the plurality of the first-contact-pads 40, the plurality of the second-contact-pads 50 and the plurality of the third-contact-pads 60; a width of each of the plurality of the second-contact-pads 50 is not consistent with a width of a corresponding first-contact-pad 40 and/or third-contact-pad 60.

In embodiments of the present disclosure, the dielectric layer is arranged between the first semiconductor chip and the first layer of the plurality of layers of the second semiconductor chips, and the size of the second-contact-pad within the dielectric layer is not consistent with the size of a corresponding first-contact-pad and/or third-contact-pad, such that it is ensured that the contact-pad with smaller size may be fully contacted with the contact-pad with larger size when being aligned, and the alignment accuracy is improved. Moreover, by arranging the dielectric layer, the insulation between adjacent contact-pads may be increased, the possibility of coupling between adjacent contact-pads may be reduced, and the problem of metal diffusion may be solved.

The first semiconductor chip 10 is a logic chip, and the second semiconductor chip is a dynamic random access memory (DRAM) chip. The logic chip may be one or more processors configured to communicate with a plurality of DRAM chips so as to access data from and store data in the plurality of DRAM chips. The logic chip includes, but is not limited to, a graphics processing unit (GPU), a field programmable gate array (FPGA), an application specific integrated circuit (ASIC), a central processing unit (CPU), or other known electronic circuit serving as a processor.

In an embodiment, the plurality of the first-contact-pads 40 include a first first-contact-pad 41 and a second first-contact-pad 42; the plurality of the second-contact-pads 50 include a first second-contact-pad 51 and a second second-contact-pad 52, and a width of the first second-contact-pad 51 is greater than a width of the second second-contact-pad 52; the plurality of the third-contact-pads 60 include a first third-contact-pad 61 and a second third-contact-pad 62; the width of the first second-contact-pad 51 is larger than a width of the first first-contact-pad 41 and/or the first third-contact-pad 61 corresponded thereto; and the width of the second second-contact-pad 52 is smaller than a width of the second first-contact-pad 42 and/or the second third-contact-pad 62 corresponded thereto.

In a group of a first-contact-pad, a second-contact-pad and a third-contact-pad corresponded to each other, if the size of the second-contact-pad is larger, the size of the first-contact-pad or the third-contact-pad is smaller, and if the size of the second-contact-pad is smaller, the size of the first-contact-pad or the third-contact-pad is larger, such that the size of the second-contact-pad is opposite to that of the corresponding first-contact-pad or third-contact-pad, and thus ensuring that the contact area of the contact-pads between the first semiconductor chip and the first layer of the plurality of layers of the second semiconductor chips after bonding is relatively constant and solving the problem of different contact area sizes due to misalignment.

It should be noted that the width is a width in a direction parallel to a plane of the first semiconductor chip.

In one embodiment, a width of each of the plurality of the first-contact-pads 40 is consistent with that of a corresponding third-contact-pad 60. The dimensions of the first-contact-pad and the third-contact-pad corresponded to each other are identical, such that the contact areas of the first-contact-pad and the third-contact-pad with the corresponding second-contact-pad are relatively in consistency.

For example, with reference to FIG. 1A, the width of the first first-contact-pad 41 is consistent with the width of the first third-contact-pad 61, and the width of the second first-contact-pad 42 is consistent with the width of the second third-contact-pad 62.

In some other embodiments, the width of the first-contact-pad may be inconsistent with that of its corresponding third-contact-pad.

In an embodiment, widths of the plurality of the first-contact-pads 40 are inconsistent; widths of the plurality of the second-contact-pads 50 are inconsistent; and widths of the plurality of the third-contact-pads 60 are inconsistent. In this way, even if there is a size difference between the bonding pads, the contact-pad with smaller size may be completely contacted with the contact-pad with larger size among the corresponding contact-pads, and thus ensuring that the contact area between the contact-pads is relatively constant.

In an embodiment, the plurality of the first contact pads 40 are formed on an active surface of the first semiconductor chip 10, and the plurality of the third-contact-pads 60 are formed on an active surface of the first layer 31 of the plurality of layers of the second semiconductor chips, and the active surface of the first semiconductor chip 10 is bonded to the active surface of the first layer 31 of the plurality of layers of the second semiconductor chips; the active surface is a surface of the chip on which a device layer is formed. Compared with bonding the active surface with a back surface, the active surface of the first semiconductor chip is bonded to the active surface of the first layer of the plurality of layers of the second semiconductor chips, such that the transmission path between the chips is shortened and the transmission speed is improved.

In some other embodiments, the plurality of the first-contact-pads 40 are formed on the active surface of the first semiconductor chip 10, and the plurality of the third-contact-pads 60 are formed on a non-active surface of the first layer 31 of the plurality of layers of the second semiconductor chips; and the active surface of the first semiconductor chip 10 is bonded to the non-active surface of the first layer 31 of the plurality of layers of the second semiconductor chips, the non-active surface is a surface opposite to the active surface. In the packaging structure, the active surfaces of the first semiconductor chip and the first layer of the plurality of layers of the second semiconductor chips both face towards a same side, and compared with the mode of bonding the active surfaces of the chips, the first layer of the plurality of layers of the second semiconductor chips does not need to be turned over additionally in this embodiment, and thus simplifying the packaging process.

In an embodiment, a material of the dielectric layer 20 includes a silicon-containing compound. Silicon-containing compound has a low Young's modulus, which can reduce the packaging stress and reduce the possibility of chip warpage.

The silicon-containing compound may be spin on glass (SOG), spin on dielectric (SOD), or other silicon-containing spin coating material.

In an embodiment, as shown in FIG. 1B, the packaging structure further includes: insulating layers 80 located between sidewalls of the plurality of the second-contact-pads 50 and the dielectric layer 20; and Young's modulus of the insulating layers 80 is smaller than Young's modulus of the dielectric layer 20.

In the actual manufacturing process, the material of the insulating layer may be an organic polymer, such as synthetic rubber, synthetic fiber, polyethylene, polyvinyl chloride, etc. By arranging the insulating layer between the second contact pad and the dielectric layer, the insulating layer has a better ductility and may be used as a buffer layer, such that the pressure of the dielectric layer on the contact pad may be reduced, and thereby reducing bonding defects and improving bonding quality.

In some other embodiments, as shown in FIG. 1A, the semiconductor packaging structure may not include the insulating layer.

The number of the second semiconductor chips stacking in the second semiconductor chip stacking structure 30 may be two, four, eight, twelve, sixteen or the like. In the embodiment of the present disclosure, as shown in FIG. 1A, the number of the second semiconductor chips stacking in the second semiconductor chip stacking structure 30 is four.

In one embodiment, the semiconductor packaging structure further includes: fourth-contact-pads 70 located within multiple layers of the plurality of layers of the second semiconductor chips above the first layer 31 of the plurality of layers of the second semiconductor chips; and widths of corresponding fourth-contact-pads 70 between adjacent two layers of the multiple layers of the plurality of layers of the second semiconductor chips are inconsistent.

As shown in FIG. 1A, the-fourth-contact pads 70 further includes contact-pads located within a side, away from the dielectric layer 20, of the first layer 31 of the plurality of layers of the second semiconductor chips.

By arranging the dimensions of the corresponding contact-pads between adjacent two layers of the plurality of layers of the second semiconductor chips being inconsistent, the contact-pads with smaller dimension may be fully contacted with the contact-pad with larger dimension when the adjacent two layers of the plurality of layers of the second semiconductor chips are aligned, thus improving the alignment accuracy and ensuring that the contact area is relatively constant.

In some embodiments, widths of the fourth-contact-pads 70 of a same layer may be equal. In some other embodiments, as shown in FIG. 1A, the widths of the fourth-contact-pads 70 of the same layer may be different.

The semiconductor packaging structure further includes: through silicon vias (TSV) located within the first semiconductor chip and the plurality layers of the second semiconductor chips, specifically located between two opposite contact-pads, and the plurality layers of the second semiconductor chips are interconnected through the contact-pads and the through silicon vias.

The semiconductor packaging structure further includes: fifth-contact-pads 92 located on a side, away from the plurality of the first-contact-pads 40, of the first semiconductor chip 10. The fifth-contact-pads 92 and the plurality of the first-contact-pads 40 are connected through the through silicon vias 91.

Solder balls 93 are formed on the fifth-contact-pads 92, and the solder balls 93 are configured to connect the semiconductor packaging structure with other elements.

The semiconductor packaging structure further includes: a packaging compound structure 100; and the packaging compound structure 100 is located on the dielectric layer 20 and the second semiconductor chip stacking structure 30, and encloses the second semiconductor chip stacking structure 30. The packaging compound structure 100 may include a silicon-containing compound. By forming the packaging compound structure 100 which encloses the second semiconductor chip stacking structure 30 and the material of which is a silicon-containing compound, the warping problem of the second semiconductor chip stacking structure 30 may be reduced, and thereby further improving the warping problem of the whole packaging structure.

The silicon-containing compound may be spin on glass (SOG), spin ondielectric (SOD), or other silicon-containing spin coating material.

In the embodiment of the present disclosure, the hybrid bond process technology is adopted between the first semiconductor chip and the second semiconductor chip and among the plurality of layers of the second semiconductor chips, so as to realize hybrid bonding stacking and improve the integration level of the packaging structure.

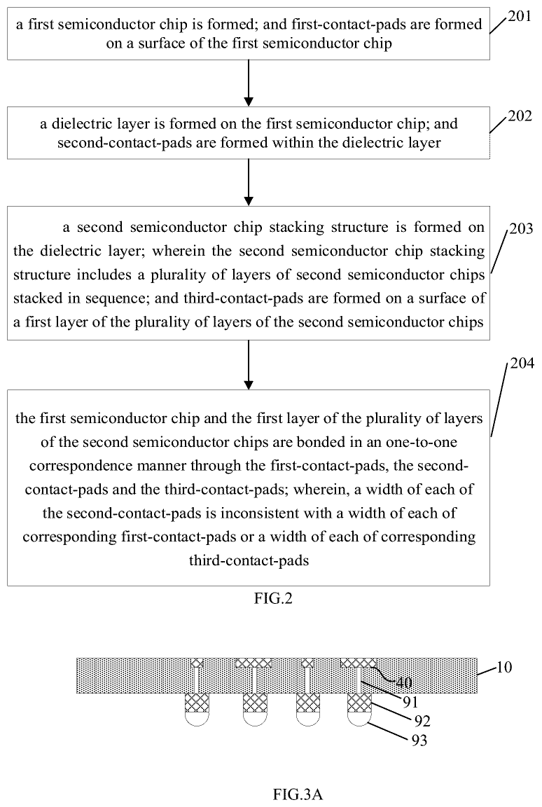

The embodiment of the present disclosure also provides a method for forming a semiconductor packaging structure, with reference to FIG. 2 for details, as shown in the figure, the method includes the following steps:
In step 201: a first semiconductor chip is formed; and a plurality of first-contact-pads are formed on a surface of the first semiconductor chip;
In step 202: a dielectric layer is formed on the first semiconductor chip; and a plurality of second-contact-pads are formed within the dielectric layer;
In step 203: a second semiconductor chip stacking structure is formed on the dielectric layer; the second semiconductor chip stacking structure includes a plurality of layers of second semiconductor chips stacked in sequence; and a plurality of third-contact-pads are formed on a surface of a first layer of the plurality of layers of the second semiconductor chips;
In step 204, the first semiconductor chip and the first layer of the plurality of layers of the second semiconductor chips are bonded in an one-to-one correspondence manner through the plurality of the first-contact-pads, the plurality of the second-contact-pads and the plurality of the third-contact-pads; a width of each of the plurality of the second-contact-pads is inconsistent with a width of a corresponding first-contact-pad and/or third-contact-pad.

The method for forming the semiconductor packaging structure provided in the embodiments of the present disclosure will be described in further detail below in combination with the specific embodiments.

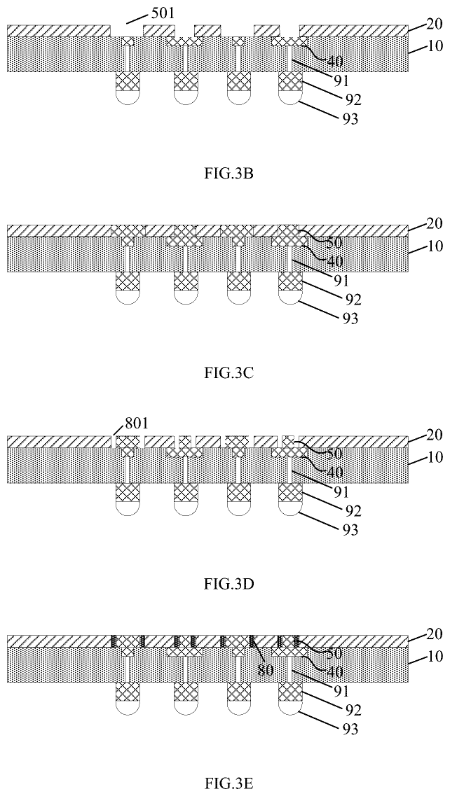

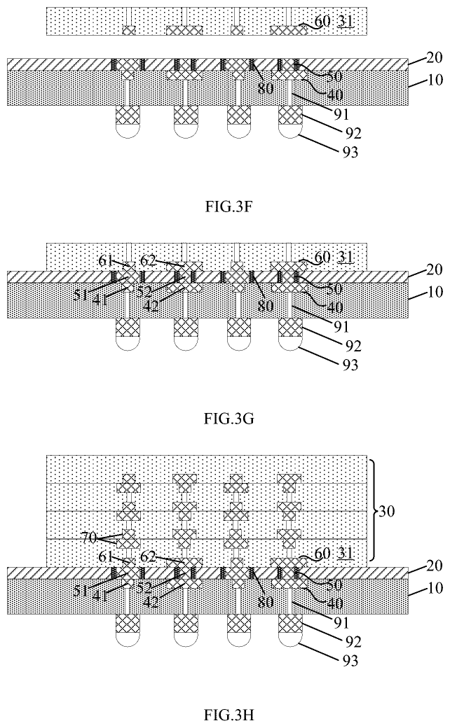

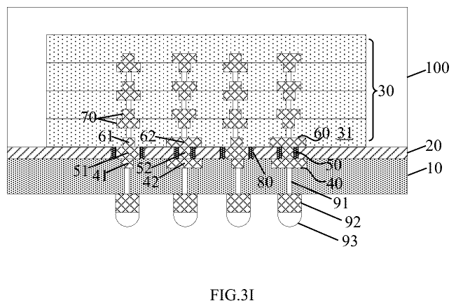

FIGS. 3A to 3I are schematic structural diagrams of a semiconductor packaging structure during the forming process provided in an embodiment of the present disclosure.

Firstly, with reference to FIG. 3A, step 201 is performed, in which a first semiconductor chip 10 is formed; and a plurality of first-contact-pads 40 are formed on a surface of the first semiconductor chip.

Specifically, before the plurality of the first-contact-pads 40 are formed, a plurality of through silicon vias 91 penetrating the first semiconductor chip 10 are firstly formed, and then one side surface of the first semiconductor chip 10 where the through silicon vias 91 are formed is etched to form a plurality of first-contact-pad through vias (not shown in the figure); then, the plurality of the first-contact-pads 40 are formed within the first-contact-pad through vias.

Continuing referring to FIG. 3A, after the plurality of the first-contact-pads 40 are formed, the method further includes: fifth-contact-pads 92 are formed on a side, away from the plurality of the first-contact-pads 40, of the first semiconductor chip 10. The fifth-contact-pads 92 and the plurality of the first-contact-pads 40 are connected through the through silicon vias 91.

Continuing referring to FIG. 3A, the method further includes: solder balls 93 are formed on the fifth-contact-pads 92, and the solder balls are configured to connect the semiconductor packaging structure with other elements.

Next, with reference to FIG. 3B and FIG. 3C, step 202 is performed, in which a dielectric layer 20 is formed on the first semiconductor chip 10; and a plurality of second-contact-pads 50 are formed within the dielectric layer 20.

Specifically, the dielectric layer 20 is formed on the first semiconductor chip 10 by spin coating, and the material of the dielectric layer 20 includes silicon-containing compound. Silicon-containing compound has a low Young's modulus, which can reduce the packaging stress and reduce the possibility of chip warpage.

The silicon-containing compound may be spin on glass (SOG), spin on dielectric (SOD), or other silicon-containing spin coating material.

The plurality of the second-contact-pads 50 are formed within the dielectric layer 20 includes: the dielectric layer 20 is etched to form a plurality of through vias 501; and the plurality of the second-contact-pads 50 are formed within the plurality of the through vias 501.

Next, with reference to FIG. 3D, the method further includes: the plurality of the second-contact-pads 50 are etched after forming the plurality of the second-contact-pads 50, such that voids 801 are formed between sidewalls of the plurality of the second-contact-pads 50 and sidewalls of the plurality of the through vias 501.

In some other embodiments, the semiconductor packaging structure may not include the void 801.

Next, with reference to FIG. 3E, the method further includes: an insulating material is filled within the voids 801 to form insulating layers 80; and Young's modulus of the insulating layers 80 is smaller than Young's modulus of the dielectric layer 20.

In the actual manufacturing process, the material of the insulating layer may be an organic polymer, such as synthetic rubber, synthetic fiber, polyethylene, polyvinyl chloride, etc. By arranging the insulating layer between the second contact pad and the dielectric layer, the insulating layer has a better ductility and may be used as a buffer layer, such that the pressure of the dielectric layer on the contact pad may be reduced, and thereby reducing bonding defects and improving bonding quality.

In some other embodiments, the semiconductor packaging structure may not include the insulating layer 80.

Next, with reference to FIG. 3F, step 203 is performed, in which a second semiconductor chip stacking structure 30 is formed on the dielectric layer 20; the second semiconductor chip stacking structure 30 includes a plurality of layers of second semiconductor chips stacked in sequence; and a plurality of third-contact-pads 60 are formed on a surface of a first layer 31 of the plurality of layers of the second semiconductor chips.

It should be noted that, in the embodiment shown in FIGS. 3F to 3H, the first layer 31 of the plurality of layers of the second semiconductor chip is firstly formed, and then the first layer 31 of the plurality of layers of the second semiconductor chip is bonded to the first semiconductor chip 10, and then other layers of the plurality of layers of the second semiconductor chips are formed on the first layer 31 of the plurality of layers of the second semiconductor chips. In some other embodiments, the second semiconductor chip stacking structure 30 may be firstly formed, and which is then bonded to the first semiconductor chip 10.

The first semiconductor chip 10 is a logic chip, and the second semiconductor chip is a dynamic random access memory (DRAM) chip. The logic chip may be one or more processors configured to communicate with a plurality of DRAM chips so as to access data from and store data in the plurality of DRAM chips. The logic chip includes, but is not limited to, a graphics processing unit (GPU), a field programmable gate array (FPGA), an application specific integrated circuit (ASIC), a central processing unit (CPU), or other known electronic circuit serving as a processor.

Specifically, with reference to FIG. 3F, the first layer 31 of the plurality of layers of the second semiconductor chips is firstly formed, and then the plurality of the through silicon vias 91 penetrating the first layer 31 of the plurality of layers of the second semiconductor chips are formed, then the side surface of the first layer 31 of the second semiconductor chip where the through silicon vias 91 are formed is etched to form the plurality of the third-contact-pad through vias (not shown in the figure), and then the plurality of the third-contact-pad 60 are formed within the plurality of the third-contact-pad through vias.

Next, with reference to FIG. 3G, step 204 is performed, in which the first semiconductor chip 10 and the first layer 31 of the plurality of layers of the second semiconductor chips are bonded in an one-to-one correspondence manner through the plurality of the first-contact-pads 40, the plurality of the second-contact-pads 50 and the plurality of the third-contact-pads 60; a width of each of the plurality of the second-contact-pads 50 is inconsistent with a width of a corresponding first-contact-pad 40 and/or third-contact-pad 60.

The dielectric layer is arranged between the first semiconductor chip and the first layer of the plurality of layers of the second semiconductor chips, and the size of the second-contact-pad within the dielectric layer is not consistent with the size of a corresponding first-contact-pad and/or third-contact-pad, such that it is ensured that the contact-pad with smaller size may be fully contacted with the contact-pad with larger size when being aligned, and the alignment accuracy is improved. Moreover, by arranging the dielectric layer, the insulation between adjacent contact-pads may be increased, the possibility of coupling between adjacent contact-pads may be reduced, and the problem of metal diffusion may be solved.

In an embodiment, with reference to FIG. 3G, the plurality of the first-contact-pads 40 include a first first-contact-pad 41 and a second first-contact-pad 42; the plurality of the second-contact-pads 50 include a first second-contact-pad 51 and a second second-contact-pad 52, and a width of the first second-contact-pad 51 is greater than a width of the second second-contact-pad 52; the plurality of the third-contact-pads 60 include a first third-contact-pad 61 and a second third-contact-pad 62; the width of the first second-contact-pad 51 is larger than a width of the first first-contact-pad 41 and/or the first third-contact-pad 61 corresponded thereto; and the width of the second second-contact-pad 52 is smaller than a width of the second first-contact-pad 42 and/or the second third-contact-pad 62 corresponded thereto.

In a group of a first-contact-pad, a second-contact-pad and a third-contact-pad corresponded to each other, if the size of the second-contact-pad is larger, the size of the first-contact-pad or the third-contact-pad is smaller, and if the size of the second-contact-pad is smaller, the size of the first-contact-pad or the third-contact-pad is larger, such that the size of the second-contact-pad is opposite to that of the corresponding first-contact-pad or third-contact-pad, and thus ensuring that the contact area of the contact-pads between the first semiconductor chip and the first layer of the plurality of layers of the second semiconductor chips after bonding is relatively constant and solving the problem of different contact area sizes due to misalignment.

In one embodiment, a width of each of the plurality of the first-contact-pads 40 is consistent with that of a corresponding third-contact-pad 60. The dimensions of the first-contact-pad and the third-contact-pad corresponded to each other are identical, such that the contact areas of the first-contact-pad and the third-contact-pad with the corresponding second-contact-pad are relatively in consistency.

For example, with reference to FIG. 3G, the width of the first first-contact-pad 41 is consistent with the width of the first third-contact-pad 61, and the width of the second first-contact-pad 42 is consistent with the width of the second third-contact-pad 62.

In some other embodiments, the width of the first-contact-pad may be inconsistent with that of its corresponding third-contact-pad.

In an embodiment, widths of the plurality of the first-contact-pads 40 are inconsistent; widths of the plurality of the second-contact-pads 50 are inconsistent; and widths of the plurality of the third-contact-pads 60 are inconsistent. In this way, even if there is a size difference between the bonding pads, the contact-pad with smaller size may be completely contacted with the contact-pad with larger size among the corresponding contact-pads, and thus ensuring that the contact area between the contact-pads is relatively constant.

In an embodiment, the plurality of the first-contact-pads 40 are formed on an active surface of the first semiconductor chip 10; the plurality of the third-contact-pads 60 are formed on an active surface of the first layer 31 of the plurality of layers of the second semiconductor chips; and the active surface of the first semiconductor chip 10 is boned with the active surface of the first layer 31 of the plurality of layers of the second semiconductor chips; the active surface is a surface of the chip on which a device layer is formed. Compared with bonding the active surface with a back surface, the active surface of the first semiconductor chip is bonded to the active surface of the first layer of the plurality of layers of the second semiconductor chips, such that the transmission path between the chips is shortened and the transmission speed is improved.

In some other embodiments, the plurality of the first-contact-pads 40 are formed on an active surface of the first semiconductor chip 10, and the plurality of the third-contact-pads 60 are formed on a non-active surface of the first layer 31 the plurality of layers of the second semiconductor chips; and the active surface of the first semiconductor chip 10 is bonded to the non-active surface of the first layer 31 the plurality of layers of the second semiconductor chips, the non-active surface is a surface opposite to the active surface. In the packaging structure, the active surfaces of the first semiconductor chip and the first layer of the plurality of layers of the second semiconductor chips both face towards a same side, and compared with the mode of bonding the active surfaces of the chips, the first layer of the plurality of layers of the second semiconductor chips does not need to be turned over additionally in this embodiment, and thus simplifying the packaging process.

Next, with reference to FIG. 3H, one or more layers of the plurality of layers of the second semiconductor chips are stacked on the first layer 31 of the plurality of layers of the second semiconductor chips to form the second semiconductor chip stacking structure 30.

The number of the second semiconductor chips stacking in the second semiconductor chip stacking structure 30 may be two, four, eight, twelve, sixteen or the like. In the embodiment of the present disclosure, as shown in FIG. 3, the number of the second semiconductor chips stacking in the second semiconductor chip stacking structure 30 is four.

In one embodiment, continuing referring to FIG. 3H, fourth-contact-pads 70 are formed within multiple layers of the plurality of layers of the second semiconductor chips above the first layer 31 of the plurality of layers of the second semiconductor chips; and widths of corresponding fourth-contact-pads 70 between adjacent two layers of the multiple layers of the plurality of layers of the second semiconductor chips are inconsistent.

As shown in FIG. 3H, the-fourth-contact pads 70 further includes contact-pads located within a side, away from the dielectric layer 20, of the first layer 31 of the plurality of layers of the second semiconductor chips.

By arranging the dimensions of the corresponding contact-pads between adjacent two layers of the plurality of layers of the second semiconductor chips being inconsistent, the contact-pads with smaller dimension may be fully contacted with the contact-pad with larger dimension when the adjacent two layers of the plurality of layers of the second semiconductor chips are aligned, thus improving the alignment accuracy and ensuring that the contact area is relatively constant.

Specifically, each layer of the plurality of layers of the second semiconductor chips is firstly formed, then the plurality of through silicon vias 91 penetrating each layer of the plurality of layers of the second semiconductor chips are formed, and then surfaces of the plurality layers of the second semiconductor chips where the through silicon vias 91 are formed are etched to form a plurality of fourth-contact-pad through vias (not shown in the figure); and then, the fourth-contact-pads 70 are formed within the plurality of the fourth-contact-pad through vias, and then each layer of the plurality of layers of the second semiconductor chips is bonded in an one-to-one correspondence manner through the fourth-contact-pads 70.

The through silicon vias 91 are located within the plurality layers of the second semiconductor chips, specifically, located between two opposite contact-pads, and the plurality layers of the second semiconductor chips are interconnected through the contact-pads and the through silicon vias.

Next, with reference to FIG. 3I, a packaging compound structure 100 is formed on the dielectric layer 20 and the second semiconductor chip stacking structure 30, and the packaging compound structure 100 encloses the second semiconductor chip stacking structure 30. The packaging compound structure 100 may include a silicon-containing compound. By forming the packaging compound structure 100 which encloses the second semiconductor chip stacking structure 30 and the material of which is a silicon-containing compound, the warping problem of the second semiconductor chip stacking structure 30 may be reduced, and thereby further improving the warping problem of the whole packaging structure.

The silicon-containing compound may be spin on glass (SOG), spin on dielectric (SOD), or other silicon-containing spin coating material.

The foregoing are only preferred embodiments of the present disclosure and are not intended to limit the scope of protection of the present disclosure. Any modification, equivalent replacement, improvement, etc. made within the spirit and principles of this disclosure shall be included in the scope of protection of this disclosure.

1. A semiconductor packaging structure, comprising:
a first semiconductor chip; wherein first-contact-pads are formed on a surface of the first semiconductor chip;
a dielectric layer located on the first semiconductor chip; wherein second-contact-pads are formed within the dielectric layer;
a second semiconductor chip stacking structure located on the dielectric layer; wherein the second semiconductor chip stacking structure comprises a plurality of layers of second semiconductor chips stacked in sequence; and third-contact-pads are formed on a surface of a first layer of the plurality of layers of the second semiconductor chips; and
the first semiconductor chip and the first layer of the plurality of layers of the second semiconductor chips are bonded to each other in an one-to-one correspondence manner through the first-contact-pads, the second-contact-pads and the third-contact-pads; and, wherein,
a width of each of the second-contact-pads is inconsistent with a width of each of corresponding first-contact-pads or a width of each of corresponding third-contact-pads.

2. The semiconductor packaging structure according to claim 1, wherein,
a width of each of the first-contact-pads is consistent with a width of each of corresponding third-contact-pads.

3. The semiconductor packaging structure according to claim 1, wherein,
the first-contact-pads are formed on an active surface of the first semiconductor chip, and the third-contact-pads are formed on an active surface of the first layer of the plurality of layers of the second semiconductor chips, and the active surface of the first semiconductor chip is bonded to the active surface of the first layer of the plurality of layers of the second semiconductor chips; wherein, the active surface is a surface of a chip on which a device layer is formed.

4. The semiconductor packaging structure according to claim 1, wherein,
widths of the first-contact-pads are inconsistent; widths of the second-contact-pads are inconsistent; and widths of the third-contact-pads are inconsistent.

5. The semiconductor packaging structure according to claim 1, wherein,
the first-contact-pads comprise a first first-contact-pad and a second first-contact-pad;
the second-contact-pads comprise a first second-contact-pad and a second second-contact-pad, wherein a width of the first second-contact-pad is greater than a width of the second second-contact-pad;
the third-contact-pads comprise a first third-contact-pad and a second third-contact-pad; and, wherein,
the width of the first second-contact-pad is larger than a width of the first first-contact-pad or the first third-contact-pad corresponded thereto; and the width of the second second-contact-pad is smaller than a width of the second first-contact-pad or the second third-contact-pad corresponded thereto.

6. The semiconductor packaging structure according to claim 1, wherein,
a material of the dielectric layer comprises a silicon-containing compound.

7. The semiconductor packaging structure according to claim 1, further comprises:
fourth-contact-pads located within multiple layers of the plurality of layers of the second semiconductor chips above the first layer of the plurality of layers of the second semiconductor chips; and,
wherein widths of corresponding fourth-contact-pads between adjacent two layers of the multiple layers of the plurality of layers of the second semiconductor chips are inconsistent.

8. The semiconductor packaging structure according to claim 1, further comprises:
insulating layers located between sidewalls of the second-contact-pads and the dielectric layer; and, wherein Young's modulus of the insulating layers is smaller than Young's modulus of the dielectric layer.

9. A method for forming a semiconductor packaging structure, comprising:
forming a first semiconductor chip; and forming first-contact-pads on a surface of the first semiconductor chip;
forming a dielectric layer on the first semiconductor chip; and forming second-contact-pads within the dielectric layer;
forming a second semiconductor chip stacking structure on the dielectric layer; wherein the second semiconductor chip stacking structure comprises a plurality of layers of second semiconductor chips stacked in sequence; and forming third-contact-pads on a surface of a first layer of the plurality of layers of the second semiconductor chips; and
bonding the first semiconductor chip and the first layer of the plurality of layers of the second semiconductor chips in an one-to-one correspondence manner through the first-contact-pads, the second-contact-pads and the third-contact-pads; and, wherein,
a width of each of the second-contact-pads is inconsistent with a width of each of corresponding first-contact-pads or a width of each of corresponding third-contact-pads.

10. The method according to claim 9, wherein,
a width of each of the first-contact-pads is consistent with a width of each of corresponding third-contact-pads.

11. The method according to claim 9, wherein,
forming the first-contact-pads on an active surface of the first semiconductor chip;
forming the third-contact-pads on an active surface of the first layer of the plurality of layers of the second semiconductor chips; and
bonding the active surface of the first semiconductor chip and the active surface of the first layer of the plurality of layers of the second semiconductor chips; wherein, the active surface is a surface of a chip on which a device layer is formed.

12. The method according to claim 9, wherein,
forming the dielectric layer on the first semiconductor chip by spin coating, and a material of the dielectric layer comprises a silicon-containing compound.

13. The method according to claim 9, further comprises:
forming fourth-contact-pads within multiple layers of the plurality of layers of the second semiconductor chips above the first layer of the plurality of layers of the second semiconductor chips; and,
wherein widths of corresponding fourth-contact-pads between adjacent two layers of the multiple layers of the plurality of layers of the second semiconductor chips are inconsistent.

14. The method according to claim 9, wherein
forming the second-contact-pads within the dielectric layer comprises:
etching the dielectric layer to form a plurality of through vias;
and forming the second-contact-pads within the plurality of the through vias; and,
wherein the method further comprises:
etching the second-contact-pads after forming the second-contact-pads, so as to form voids between sidewalls of the second-contact-pads and sidewalls of the plurality of the through vias.

15. The method according to claim 14, further comprises:
filling an insulating material within the voids to form insulating layers; wherein Young's modulus of the insulating layers is smaller than Young's modulus of the dielectric layer.

16. A semiconductor packaging structure, comprising:
a first semiconductor chip; wherein first-contact-pads are formed on a surface of the first semiconductor chip;
a dielectric layer located on the first semiconductor chip; wherein second-contact-pads are formed within the dielectric layer; and
a second semiconductor chip stacking structure located on the dielectric layer; wherein the second semiconductor chip stacking structure comprises a plurality of layers of second semiconductor chips stacked in sequence; and third-contact-pads are formed on a surface of a first layer of the plurality of layers of the second semiconductor chips; and
the first semiconductor chip and the first layer of the plurality of layers of the second semiconductor chips are bonded to each other in an one-to-one correspondence manner through the first-contact-pads, the second-contact-pads and the third-contact-pads; and, wherein,
a width of each of the second-contact-pads is inconsistent with a width of each of corresponding first-contact-pads and a width of each of corresponding third-contact-pads.

17. The semiconductor packaging structure according to claim 1, wherein,
the first-contact-pads comprise a first first-contact-pad and a second first-contact-pad;
the second-contact-pads comprise a first second-contact-pad and a second second-contact-pad, wherein a width of the first second-contact-pad is greater than a width of the second second-contact-pad;
the third-contact-pads comprise a first third-contact-pad and a second third-contact-pad; and, wherein,
the width of the first second-contact-pad is larger than a width of the first first-contact-pad or the first third-contact-pad corresponded thereto; and the width of the second second-contact-pad is smaller than a width of the second first-contact-pad and the second third-contact-pad corresponded thereto.

18. The semiconductor packaging structure according to claim 1, wherein,
the first-contact-pads comprise a first first-contact-pad and a second first-contact-pad;
the second-contact-pads comprise a first second-contact-pad and a second second-contact-pad, wherein a width of the first second-contact-pad is greater than a width of the second second-contact-pad;
the third-contact-pads comprise a first third-contact-pad and a second third-contact-pad; and, wherein,
the width of the first second-contact-pad is larger than a width of the first first-contact-pad and the first third-contact-pad corresponded thereto; and the width of the second second-contact-pad is smaller than a width of the second first-contact-pad or the second third-contact-pad corresponded thereto.

19. The semiconductor packaging structure according to claim 1, wherein,
the first-contact-pads comprise a first first-contact-pad and a second first-contact-pad;
the second-contact-pads comprise a first second-contact-pad and a second second-contact-pad, wherein a width of the first second-contact-pad is greater than a width of the second second-contact-pad;
the third-contact-pads comprise a first third-contact-pad and a second third-contact-pad; and, wherein,
the width of the first second-contact-pad is larger than a width of the first first-contact-pad and the first third-contact-pad corresponded thereto; and the width of the second second-contact-pad is smaller than a width of the second first-contact-pad and the second third-contact-pad corresponded thereto.

20. The method according to claim 9, wherein,
the width of each of the second-contact-pads is inconsistent with the width of each of corresponding first-contact-pads and the width of each of corresponding third-contact-pads.
